(19) United States
(12) Patent Application Publication
(10) Pub. No.: US 2024/0018642 A1
(43) Pub. Date: Jan. 18, 2024

(54) HARD CUBIC AL-RICH ALTIN COATING LAYERS PRODUCED BY PVD FROM CERAMIC TARGETS

(71) Applicant: Oerlikon Surface Solutions AG, Pfäffikon, Pfäffikon (CH)

(72) Inventor: Siva Phani Kumar YALAMANCHILI, Sargans (CH)

(21) Appl. No.: 18/257,414

(22) PCT Filed: Dec. 16, 2021
(86) PCT No.: PCT/EP2021/086191

§ 371 Date: Jun. 23, 2023

Related U.S. Application Data
(60) Provisional application No. 63/126,040, filed on Dec. 16, 2020.

(51) Int. Cl. C23C 14/06; C23C 14/00; C23C 14/32

(52) U.S. Cl. CPC C23C 14/0617; C23C 14/0021; C23C 14/325

(57) ABSTRACT

A PVD coating process, preferably an arc evaporation PVD coating process for producing an aluminum-rich AlₓTi₁₋ₓN-based thin film having an aluminium content of >70 at-% based on the total amount of aluminium and titanium in the thin film, a cubic crystal structure and an at least partially non-columnar microstructure with a non-columnar content of >1 vol-% based on the volume of the total microstructure, wherein ceramic targets are used as material source for the aluminium-rich AlₓTi₁₋ₓN-based thin film.

The present invention relates to coatings consisting of or comprising one or more hard cubic Al-rich AlTiN coating layers (hereafter also simply referred to as hard cubic Al-rich AlTiN layers or hard cubic Al-rich AlTiN films) produced by a physical vapour deposition (PVD) process from ceramic targets as well as a method for producing thereof.

A hard cubic Al-rich AlTiN coating layer according to the present invention may be understood as a coating layer consisting of aluminium (Al), titanium (Ti) and nitrogen (N) or as a coating layer comprising aluminium (Al), titanium (Ti) and nitrogen (N) as main components, exhibiting a cubic crystal structure and hardness of 30 GPa, preferably of 35 GPa or more.

The term ‘exhibiting a cubic crystal structure’ may be understood as exhibiting only cubic phase, i.e. no hexagonal phase at all. However, this does not mean that traces or small amounts of preferably less than 0.5 wt-% relative to the total mass of the coating layer may have a different phase.

In this context, the use of the term “Al, Ti and N as main components” in the Al-rich AlTiN layer means in particular that the sum of the content of Al, Ti and N in the Al-rich AlTiN layer as concentration in atomic percentage corresponds to more than 50 at % (i.e. a value between >50 at % and 100 at %), preferably more than 75 at % (i.e. a value between >75 at % and 100 at %), more preferably equal to or more than 80 at % (i.e. a value between 80 at % and 100 at %), if all chemical elements contained in the Al-rich AlTiN layer are considered for the determination of the whole chemical elements composition of the Al-rich AlTiN layer in atomic percentage.

The term “Al-rich” in this context may be used in particular for indicating that the content of aluminium (Al) in the corresponding Al-rich AlTiN layer is equal to or preferably more than 70 at %, if only Al and Ti are considered for the determination of a chemical elements composition in atomic percentage (i.e. Al[at %]/Ti[at %]≥70/30).

### STATE OF THE ART

AlTiN coating layers having Al content above 75 at.-% (in relation to Ti), exhibiting a cubic crystal structure and a columnar micro-structure are known to be synthesized by LP-CVD processes.

These kinds of coatings are known to show superior wear protection compared to the coatings with lower Al-content, such as PVD based Al_{0.67}Ti_{0.33}N coatings.

Historically, it is well known that PVD methods such as arc deposition, and reactive magnetron sputtering can be used for producing metastable cubic (B1 crystal structure) phased AlTiN layers with a maximum of 70 at.-% Al.

Furthermore, there are also some publications presenting possible methods for enhancing the metastable solubility limits of Al beyond 70 at. %. However, all these until now proposed methods involving some disadvantages or limitations. One limitation is for example the deposition of only cubic phase with columnar structure, which increases the coating effort, in particular the coating time. In addition, when depositing cubic phases with an exclusively columnar structure, care must be taken to ensure that the deposition conditions are particularly gentle.

### OBJECTIVE OF THE PRESENT INVENTION

An objective of the present invention is to provide a method for producing hard cubic Al-rich AlTiN coating layers, which overcome or alleviate the disadvantages or limitations of the state of the art.

The hard cubic Al-rich AlTiN coating should preferably exhibit 100% cubic phase, high hardness, appropriate compressive stress and a coating microstructure, which preferably allows attaining high wear resistance and improved cutting performance, if the Al-rich AlTiN coating is applied on cutting tools. In addition, the coating layer according to the invention should be producible in a simple and fast matter.

### DESCRIPTION OF THE PRESENT INVENTION

The objectives of the present invention are achieved by providing a coating comprising at least one hard cubic Al-rich AlTiN coating layer as described hereafter and claimed in claim 10 and a method for producing thereof as described hereafter and claimed in claim 1.

In a first aspect of the present invention, disclosed is a PVD coating process, preferably an arc evaporation PVD coating process for producing an aluminum-rich Al_{X}Ti_{1-X}N-based thin film having an aluminium content of >70 at-% based on the total amount of aluminium and titanium in the thin film, a cubic crystal structure and an at least partially non-columnar microstructure with a non-columnar content of >1 vol-% based on the volume of the total microstructure, wherein ceramic targets are used as material source for the aluminium-rich Al_{X}Ti_{1-X}N-based thin film.

In another example of the first aspect, an arc evaporation PVD coating process is used as PVD coating process.

In another example of the first aspect, the aluminum-rich Al_{X}Ti_{1-X}N-based thin film may have a mixed columnar and non-columnar microstructure with a content of >1 vol-% of the non-columnar microstructure, preferably with a content of >20 vol-% of the non-columnar microstructure, in particular with a content of >50 vol-% of the non-columnar microstructure.

In another example of the first aspect, the aluminum-rich Al_{X}Ti_{1-X}N-based thin film having a non-columnar microstructure.

Moreover, in another example of the first aspect, brittle and insulating ceramic targets are used.

In another example of the first aspect, preferably arc currents >80 Ampere may be used, wherein in particular arc currents between 80 and 200 Ampere may be used.

In another example of the first aspect, at least one target is equipped with an additional insulator in the middle, and the arc steering is manipulated in a way for the ceramic target not to crack during arc discharge.

In another example of the first aspect, Al_{X}Ti_{1-X}N may be used as target material, wherein X is ≥75, wherein X preferably may have a value between 75 and 90.

Furthermore, in another example of the first aspect, at least one ceramic target is 99% dense and crack free even during the processing.

In another example of the first aspect, Al_{X}Ti_{1-X}N may be used as target material, wherein the AlN-content may be >70 Vol-%, preferably >75 Mol-% of the target material.

In another example of the first aspect, nitrogen may be introduced as reactive gas, wherein nitrogen preferably may be introduced with a pressure of less than 0.5 Pa, in particular with a pressure between 0.3 and 0.1 Pa.

In another example of the first aspect, a negative bias voltage may be applied to the substrate to be coated, wherein the bias voltage applied to the substrate preferably may range between −250 V and −30 V, more preferably between −200 V and −80 V, in particular between −200 V and −100 V.

In another example of the first aspect, the deposition temperature during the coating process may be lower than 360° C., preferably between 150° C. and 320° C.

In another example of the first aspect, a plurality of aluminum-rich Al_{X}Ti_{1-X}N-based thin films may be deposited one above the other to produce a multilayer film, wherein the content of the Al_{X}Ti_{1-X}N showing a non-columnar microstructure in spite of cubic structure variates with respect to adjacent layers.

In a second aspect of the present invention, disclosed is an aluminium-rich AlₓTi₁₋ₓN-based thin film having an aluminium content of >70 at-% based on the total amount of aluminium and titanium in the thin film, a cubic crystal structure and at least partially non-columnar microstructure with a non-columnar content of >1 vol-% based on the total microstructure, producible by a process according to first aspect of the present invention.

In another example of the second aspect, the aluminum-rich Al_{X}Ti_{1-X}N-based thin film may have a mixed columnar and non-columnar microstructure with a content of >1 vol-% of the non-columnar microstructure, preferably with a content of >20 vol-% of the non-columnar microstructure, in particular with a content >50 vol-% of the non-columnar microstructure.

In another example of the second aspect, the thin film may comprise Al, Ti and N as main components and may have a chemical elements composition in atomic percentage regarding these elements according to formula (AlₐTi_{b})ₓN_{y}, wherein a and b are respectively the concentration of aluminium and titanium in atomic ratio considering only Al and Ti for the calculation of the element composition in the layer, whereby a+b=1 and 0≠a≥0.7 and 0≠b≥0.2, or 0≠a≥0.8 and 0≠b≤0.2, and wherein x is the sum of the concentration of Al and the concentration of Ti, and y is the concentration of nitrogen in atomic ratio considering only Al, Ti and N for the calculation of the element composition in the layer, whereby preferably x+y=1 and 0.45≤x≤0.55

In another example of the second aspect, the thin film may show a hardness of ≥30 GPa, preferably a hardness of ≥35 GPa, measured using instrumented indentation in conformance with ISO 14577-1.

In another example of the second aspect, the thin film may show a reduced Young's modulus in a range between 350 GPa and 480 GPa, preferably in a range between 370 GPa and 410 GPa, measured using instrumented indentation in conformance with ISO 14577-1.

In another example of the second aspect, the thin film may show a compressive stress of more than 2.5 GPa, preferably a compressive stress in a range between 2.5 GPa and 6 GPa, measured using instrumented indentation in conformance with ISO 14577-1.

In another example of the second aspect, the thin film shows a high adhesion of HF 1 even at 5 μm coating thickness, wherein this high adhesion in particular resulting from the deposition of the thin film by the combination of using ceramic targets and arc discharge

In another example of the second aspect, the aluminum-rich Al_{X}Ti_{1-X}N-based thin film may be formed as a multilayer film, comprising a plurality of aluminum-rich Al_{X}Ti_{1-X}N-based thin films deposited one above the other, wherein preferably the content of the Al_{X}Ti_{1-X}N may showing a non-columnar microstructure may variate with respect to adjacent layers.

In another example of the second aspect, the thin film may have an aluminium content of X≥75, preferably an aluminium content of X between 75 and 90.

In another example of the second aspect, the layer thickness may be >500 nm, preferably >1000 nm, in particular >1500 nm.

In a third aspect of the present invention, disclosed is the use of an aluminium-rich AlₓTi₁₋ₓN-based thin film according to the second aspect of the invention for manufacturing a coated tool or a coated component, especially a coated cutting tool or a coated forming tool or a coated turbine component or a coated component to be used in wear resistant applications.

As at least partially mentioned before and in order to summarize some important aspects of the invention, the present invention in particular relates concretely to a coating layer comprising Al, Ti and N as main components and having chemical elements composition in atomic percentage regarding these elements according to formula (AlₐTi_{b})ₓN_{y}, where a and b are respectively the concentration of aluminium and titanium in atomic ratio considering only Al and Ti for the calculation of the element composition in the layer, whereby a+b=1 and 0≠a≥0.7 and 0≠b≥0.2, or 0≠a≥0.8 and 0≠b≥0.2, and where x is the sum of the concentration of Al and the concentration of Ti, and y is the concentration of nitrogen in atomic ratio considering only Al, Ti and N for the calculation of the element composition in the layer, whereby x+y=1 and 0.45≤x≤0.55, wherein:
the coating layer may exhibit:
   100% fcc cubic phase,
   hardness H≥35 GPa,
   reduced Young's modulus Er (Er=E÷v²) in a range between 350 GPa and 480 GPa, i.e 350 GPa≤Er≤480 GPa, more preferably in a range between 370 GPa and 410 GPa, i.e 370 GPa≤Er≤410 GPa. Hardness, and reduced elastic modulus are measured using Instrumented indentation, in conformance with ISO 14577-1 test method.
   compressive stress of 2.5 GPa or more, for example between 2.5 GPa and 6 Pa.
   either a columnar or a non-columnar structure or a structure composed of a sequential layering of columnar and non-columnar modulated layers while having 100% cubic phase with the composition of AlTiN, where AlN>0.7 moles.
   compressive stress between 4 and 6 GPa and simultaneously displaying adhesion of HF1 even with a coating thickness of 5 μm.

Furthermore, the present invention in particular relates concretely to a method for producing a coating layer according to the first aspect of the present invention on a surface of a substrate, wherein:
the coating layer may be formed in the interior of a vacuum coating chamber by using PVD cathodic arc evaporation techniques, wherein in particular:
   at least one arc evaporation source comprising a target of an insulating ceramic material, in particular a target consisting of an insulating AlN with a mole fraction higher than 70%, operated as cathode for evaporating the target material may be used,
   target material may consist of Al, Ti and N or may comprise Al, Ti and N as main components, wherein in particuar:
      if only considering the content of Al, Ti and N in atomic percentage in the target material, then the composition in atomic percentage regarding these elements according to the formula (Al_{c}Ti_{d})ₜN_{z}, where c and d are respectively the concentration of aluminium and titanium in atomic ratio considering only Al and Ti for the calculation of the element composition in the layer, whereby c+d=1, c/d≥70/30 and 0≠c≥0.7 and 0≠d≥0.10, and where t is the sum of the concentration of Al and the concentration of Ti, and z is the concentration of nitrogen in atomic ratio considering only Al, Ti and N for the calculation of the element composition in the layer, whereby t+z=1 and 0.45≤z≤0.55, preferably z=0.5
   the method may further involve a deposition of aluminium titanium nitride from the insulating ceramic target, wherein nitrogen gas is introduced in the vacuum coating chamber for compensating any loss of nitrogen provided from the target during coating process,
   the deposition of aluminium titanium nitride may be carried out
      at a deposition temperature of less than 360° C., preferably between 150° C. and 320° C.,
      at a nitrogen partial pressure of less than 0.5 Pa, preferably between 0.1 Pa and 0.3 Pa,
      by using a bias voltage Ub in a range corresponding to −250 V≤Ub≤−30V, preferably in a range corresponding to −200 V≤Ub≤−80V, more preferably in a range corresponding to −200 V≤Ub≤−100V,
      the insulating ceramic target may be equipped with an insulator inside the insulating target as presented by Krassnitzer in PCT/EP2020/068828. Surprisingly this setup has enabled to maintain a stable arc discharge in a wide range of currents i.e. from 80 A to 200 Amps in spite the targets has an insulating material with more than 70% mole fraction,
      a stable arc discharge of an insulating ceramic target in a low working pressure of less than or equal to 0.2 Pa.

Therefore, to enable the arc discharge of a ceramic target, and to attain a stable arc discharge, preferably the method may be carried out by using one or more arc evaporation sources as they are described by Krassnitzer in PCT/EP2020/068828. In this manner it is possible to conduct the reactive PVD coating process and to produce the Al-rich AlTiN coating layer (with Al content higher than 75 at % as explained above) in a manner that an arc current of for example 200 A can be applied to the ceramic target and at the same time attaining a discharge voltage of more than 30V in the arc discharge, but maintaining a contribution of less than 20% of the electrical power that results in the substrate heating.

AlTiN with Al>75% preferable may be grown in cubic structure and high hardness at low temperature, low gas pressure (high energy input from ions) and high bias voltage.

The inventors have found that the combination of Al and Ti in the above mentioned ratio in the Al-rich AlTiN layer, it means Al [at %]/Ti [at %]≤70/30, preferably Al [at %]/Ti [at %]>70/30, more preferably 90/10 Al [at %]/Ti [at %]≤75/25, has shown a big contribution for improvement of wear protection to tools and/or components.

Furthermore, the present invention in particular relates to coatings systems including one or more inventive hard cubic Al-rich AlTiN coating layers.

The inventive method mentioned above for producing the above the inventive hard cubic Al-rich AlTiN coating layers can be also modified by using for example further targets and/or reactive gas flows in order to produce other kind of coating layers to be combined with the inventive hard cubic Al-rich AlTiN coating layers in order to produce different coating systems, e.g. as multilayer and/or gradient coating systems.

The Al-rich AlTiN coating layers and/or coating systems according to the present invention (i.e. comprising Al-rich AlTiN coating layers according the present invention) exhibit excellent mechanical properties, and is expected to have beneficial set of properties for providing superior performance to tools and components subjected to wear and stress collective.

The above mentioned inventive (AlₐTi_{b})ₓN_{y} layers may exhibit 100% face-centered cubic (fcc) structure. Importantly, the present invention describes the method to produce the inventive Al-rich AlTiN coating by a physical vapour deposition (PVD) process in particular by arcing an insulating ceramic AlTiN target or targets comprising AlTiN, having more than 70 at % of Al in relation to Ti, and by simultaneous introduction of controlled N₂ gas into the vacuum coating chamber (also called PVD apparatus). Furthermore, the present invention shows how to synthesize Al-rich AlTiN both in columnar and non-columnar structure while retaining only cubic phase in spite of high AlN fraction. Surprisingly it is also found that the thin film synthesized with insulating ceramic targets shows a superior adhesion to substrate compared to when metallic targets are used as shown in FIG. 9.

### DETAILED DESCRIPTION

For providing a better understanding of the present invention, some Examples, Tables and Figures will be used below for describing the invention in more detail. However, these Examples, Tables and Figures should not be understood as a limitation of the present invention but only as concrete examples and/or preferred embodiments of the present invention.

The inventive examples of hard cubic Al-rich AlTiN layers deposited according to the present invention, as described below, were conducted by using an cathodic arc evaporation process at a process temperature of 300° C. (in this context the term “process temperature” is used for referring in particular to the set temperature during the coating deposition process) and at a low nitrogen partial pressure between 0.2 Pa and 0.15 Pa. Targets with chemical elements composition of (Al_{0.77}Ti_{0.23})_{0.5}N_{0.5} were used and the targets were operated as cathode by applying an arc current between 80 A and 200 A and a substrate bias voltage of −120 V, and a nitrogen partial pressure between 0.15 Pa and 0.20 Pa.

Two inventive examples of such inventive deposition processes with detailed process parameters as well as the measured coating layer properties as deposited in these inventive examples are given in Table 1.1 and 1.2.

Three comparative examples of non-inventive deposition processes with detailed process parameters as well as the measured coating layer properties as deposited in these comparative examples are given in Table 2.1 and 2.2.

The SEM and X-ray examinations of the inventive hard cubic Al-rich AlTiN coatings obtained by coating processes given in the inventive examples 1 to 2 are shown in FIGS. 1 to 4.

The SEM and X-ray examinations of the non-inventive Al-rich AlTiN coatings obtained by coating processes given in the comparative examples 3 to 5 are shown in FIGS. 5 to 10.

### FIGURES

FIG. 1: SEM fracture cross-section image of the hard cubic Al-rich AlTiN coating film deposited according to the inventive Example 1

FIG. 2: SEM fracture cross-section image of the hard cubic Al-rich AlTiN coating film deposited according to the inventive Example 1

FIG. 3: X-ray patters of as-deposited hard cubic Al-rich AlTiN coating film deposited according to the inventive Example 1 and Example 2.

FIG. 4: SEM fracture cross-section image of the Al-rich AlTiN coating film deposited according to the comparative Example 3.

FIG. 5: SEM fracture cross-section image of the Al-rich AlTiN coating film deposited according to the comparative Example 4

FIG. 6: SEM fracture cross-section image of the Al-rich AlTiN coating film deposited according to the comparative Example 5

FIG. 7: X-ray patters of as-deposited Al-rich AlTiN coating film deposited according to the comparative Example 3.4, and 5.

FIG. 8: Ceramic target adapted for reliable operation as cathode in a cathodic arc deposition source.

FIG. 9: X-SEM (a), and coating resistance to flaking under HRC indention(b) of inventive coating coatings (#2620, and #3007), and comparative (#2301) coating.

TABLE 1.1
Coating process parameters used by inventive examples

| | Ceramic target | | Arc current | N₂ | | Deposition |
|---|---|---|---|---|---|---|
| Inventive | composition | Temperature | at target | pressure | Bias | time |
| Examples | [at %] | [° C.] | [A] | [Pa] | voltage | [min] |
| 1 | Al_{0.385}Ti_{0.115}N_{0.5} | 300 | 80 | 0.15 | −120 V | 300 |
| 2 | Al_{0.385}Ti_{0.115}N_{0.5} | 300 | 200 | 0.20 | −120 V | 180 |

TABLE 1.2
Coating properties of hard cubic Al-rich AlTiN
layers produced by inventive examples

| | | | | Structure | | Reduced |
|---|---|---|---|---|---|---|
| | | | | growth/ | Hard- | Young's |
| Inventive | Al | Ti | N | crystalline | ness | modulus |
| Examples | [at %] | [at %] | [at %] | phase | [GPa] | [GPa] |
| 1 | 36.44 | 11.76 | 51.8 | Mainly | 41 ± 3 | 410 ± 15 |
| | | | | columnar/ | | |
| | | | | fcc | | |
| 2 | 36.81 | 11.56 | 51.63 | non- | 37 ± 2 | 377 ± 15 |
| | | | | columnar/ | | |
| | | | | fcc | | |

TABLE 2.1
Coating process parameters used by comparative examples

| | Metallic target | | Arc current | N₂ | | Deposition |
|---|---|---|---|---|---|---|
| Comparative | composition | Temperature | at target | pressure | Bias | time |
| Examples | [at %] | [° C.] | [A] | [Pa] | voltage | [min] |
| 3 | Al₇₅Ti₂₅ | 200 | 200 | 1.50 | −120 V | 140 |
| 4 | Al₇₅Ti₂₅ | 200 | 200 | 2.00 | −120 V | 140 |
| 5 | Al₇₅Ti₂₅ | 200 | 200 | 2.50 | −120 V | 140 |

TABLE 2.2
Coating properties of hard cubic Al-rich AlTiN
layers produced by comparative examples

| | | | | Structure | | Reduced |
|---|---|---|---|---|---|---|
| Compar- | Al | Ti | N | growth/ | | Young's |
| ative | [at | [at | [at | crystalline | Hardness | modulus |
| Examples | %] | %] | %] | phase | [GPa] | [GPa] |
| 3 | 37 | 12.5 | 51 | non- | 32.2 ± 2 | 295 ± 8 |
| | | | | columnar/ | | |
| | | | | mix of | | |
| | | | | cubic and | | |
| | | | | hexagonal | | |
| 4 | 36.6 | 13.5 | 50 | non- | 34.9 ± 2 | 290 ± 9 |
| | | | | columnar/ | | |
| | | | | mix of | | |
| | | | | cubic and | | |
| | | | | hexagonal | | |
| 5 | 36.6 | 13.4 | 50 | Columnar | 40 ± 2 | 383 ± 9 |
| | | | | and cubic | | |

The film structural analyses were conducted by X-ray diffraction (XRD) using a PANalytical X'Pert Pro MPD diffractometer equipped with a CuKa radiation source. The diffraction patterns were collected in Bragg-Brentano geometry. Micrographs of the film fracture cross-sections were obtained with a FEGSEM Quanta F 200 Scanning Electron Microscope (SEM).

The hardness and indentation modulus of the as-deposited samples were determined using an Ultra-Micro-Indentation System equipped with a Berkovich diamond tip. The testing procedure included normal load of 10 mN. The hardness values were evaluated according to the Oliver and Pharr method. Thereby, we assured an indentation depth of less than 10% of the coating thickness to minimize substrate interference.

As shown in Table 1.2 shows a mainly columnar microstructure, but with at least 1 wt-% non-columnar microstructure, already allowing a facilitated coating.

### FIGURES

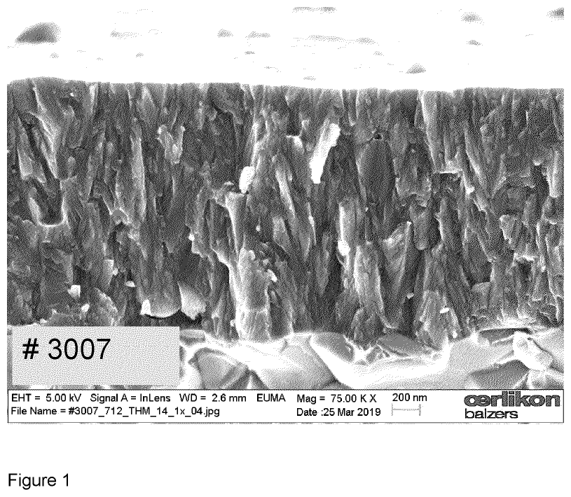

FIG. 1: SEM fracture cross-section image of the hard cubic Al-rich AlTiN coating film deposited according to the inventive Example 1

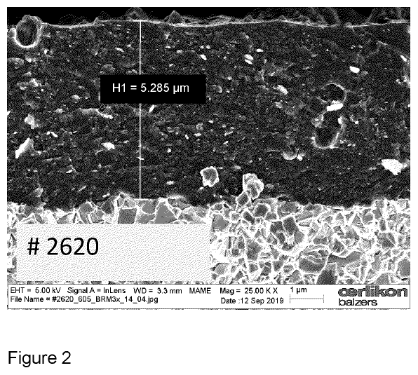

FIG. 2: SEM fracture cross-section image of the hard cubic Al-rich AlTiN coating film deposited according to the inventive Example 1

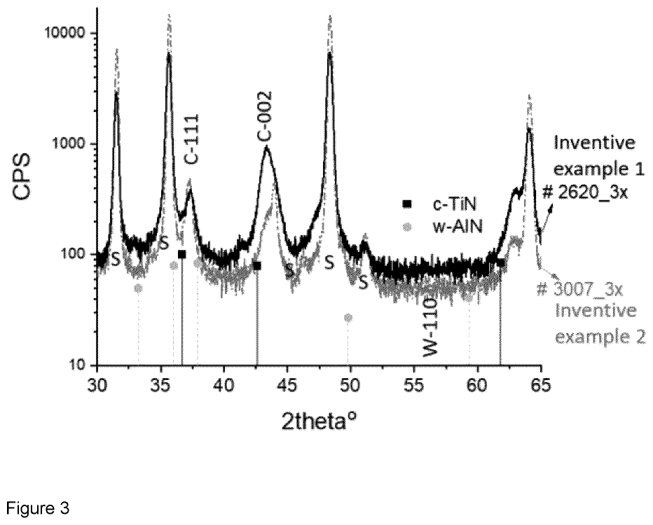

FIG. 3: X-ray patters of as-deposited hard cubic Al-rich AlTiN coating film deposited according to the inventive Example 1 and Example 2.

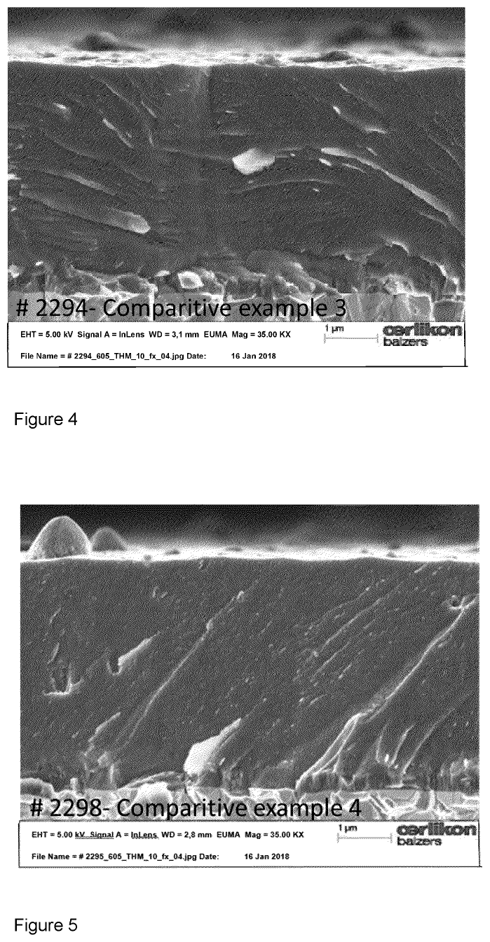

FIG. 4: SEM fracture cross-section image of the Al-rich AlTiN coating film deposited according to the comparative Example 3.

FIG. 5: SEM fracture cross-section image of the Al-rich AlTiN coating film deposited according to the comparative Example 4

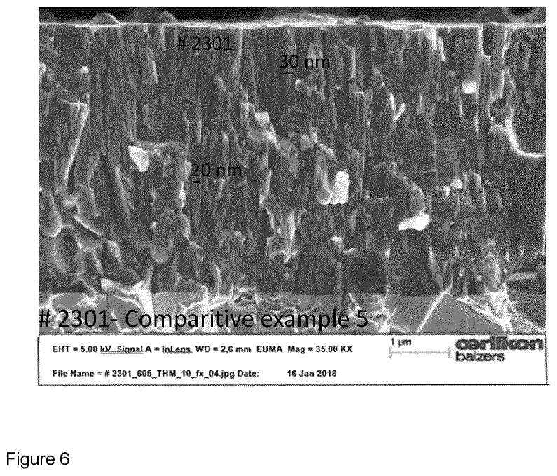

FIG. 6: SEM fracture cross-section image of the Al-rich AlTiN coating film deposited according to the comparative Example 5

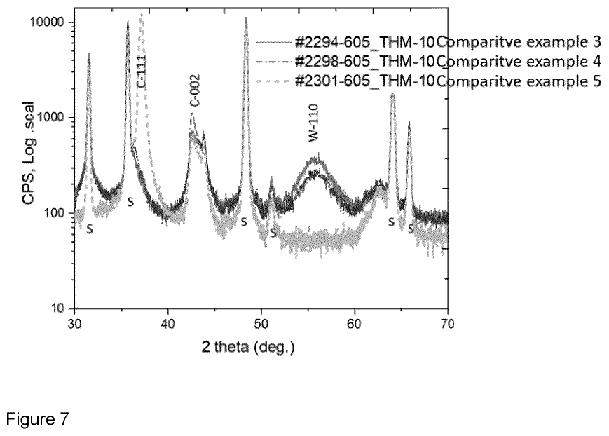

FIG. 7: X-ray patters of as-deposited Al-rich AlTiN coating film deposited according to the comparative Example 3.4, and 5.

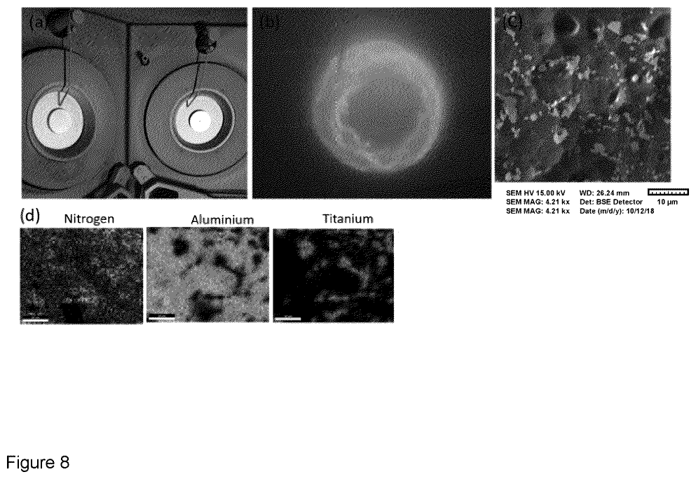

FIG. 8: Ceramic target adapted for reliable operation as cathode in a cathodic arc deposition source.

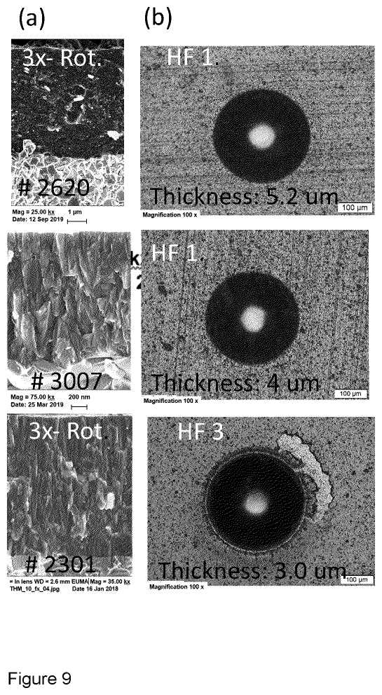

FIG. 9: X-SEM (a), and coating resistance to flaking under HRC indention(b) of inventive coating coatings (#2620, and #3007), and comparative (#2301) coating.

To produce inventive Al-rich AlTiN-based film and a tunable microstructure, the inventors used an arc deposition process on an insulating ceramic targets with minimum of 70 at % of Al in relation to the Ti content, in which the inventive combination of the deposition parameters were selected based on the following understanding:
a) at target: Arc discharge current, distribution and strength of the magnetic field are chosen to form the desired plasma state of film forming species, consisting of single and multiple charges ions of Al, Ti, and N, wherein the Arc current is varied between 80 A and 200 A to switch the microstructure between columnar and noncolumnar structure.
b) at substrate: Bias voltage is high enough to increase the kinetic energy, thereby increasing the quench rate of incident ions at the thin film growth front. Simultaneously, substrate temperature is low enough to freeze the ad-atom mobility on the growth front.
c) general: Nitrogen gas pressure is manipulated within the desired window, that is low enough to reduce the population of nitrogen ions, there by supressing the nucleation of hexagonal phase enabled by gas ion induced remixing effects on the growth surface, and the nitrogen gas pressure is sufficiently high enough to form stoichiometric AlTiN thin film.

By optimizing the abovementioned process levers of the arc deposition, nucleation of thermodynamically favoured hexagonal phase is supressed at the growth surface, and there by the metastable solubility of Al in the c-AlTiN has been raised to higher concentration with more than 75 at. % (e.g. 80 at. %). Furthermore, surprisingly, the microstructure could be tuned between columnar and non-columnar while retaining single phase cubic solid solution.

### Particular Advantages of the Present Invention

The present invention provides a method which allows:
Synthesis of stochiometric and cubic Al-rich AlTiN thin films by Arc evaporation of ceramic targets with composition of Al₇₇Ti₂₃N or even comprising a higher content of Al in relation to Ti, e.g. till a composition of Al₉₀Ti₁₀N.
Selecting parameters for stable arc discharge of ceramic targets with more than 70% vol fraction of semiconducting AlN by using a nitrogen gas pressure less than 0.2 Pa—Generally, under such low gas pressure, is difficult to maintain a smooth arc movement, but ceramic targets used according to the present invention facilitate low pressure operation.
Synthesis of both columnar, and non-columnar cubic phase solid solution with a composition of Al₇₇Ti₂₃N or even comprising a higher content of Al in relation to Ti, e.g. till a composition of Al₉₀Ti₁₀N.
Synthesis of Al-rich AlTiN films processed via ceramic targets, which show a superior resistance to HRC indentation induced flaking compared to thin films processed via metallic targets.
Arc discharge of insulating ceramic targets for producing coatings with composition of AlTiN comprising a content of AlN>75 mol %, wherein the deposition is possible by using a wide range of Arc currents between 80 A and 200 A and maintain a stable Arc discharge at low gas pressure of less than 0.2 Pa.
Synthesis of AlTiN with cubic structure and content of AlN>75 mol %, in both columnar and non-columnar microstructures, and even as a modulated layer of columnar and non-columnar structures.
Synthesis of AlTiN with cubic structure and content of AlN>75 mol % in both columnar and non-columnar microstructures, deposited by Arc evaporation from insulating ceramic targets, the deposited coating exhibiting very good adhesion to the substrate (HF 1) in spite a high compressive stress of even 5 GPa, and high thickness of even 5 μm.

What is claimed is:

1. A PVD coating process for producing an aluminum-rich Al_{X}Ti_{1-X}N-based thin film having an aluminium content of >70 at-% based on the total amount of aluminium and titanium in the thin film, a cubic crystal structure and an at least partially non-columnar microstructure with a non-columnar content of >1 vol-% based on the volume of the total microstructure, wherein ceramic targets are used as material source for the aluminium-rich Al_{X}Ti_{1-X}N-based thin film.

2. Coating process according to claim 1, wherein an arc evaporation PVD coating process is used as PVD coating process.

3. Coating process according to claim 1,
wherein the aluminum-rich Al_{X}Ti_{1-X}N-based thin film having a mixed columnar and non-columnar microstructure with a content of >1 vol-% of the non-columnar microstructure.

4. Coating process according to claim 1, wherein the aluminum-rich Al_{X}Ti_{1-X}N-based thin film having a non-columnar microstructure.

5. Coating process according to claim 1, wherein
brittle and insulating ceramic targets are used.

6. Coating process according to claim 2,
wherein arc currents >80 Ampere are used, wherein in particular arc currents between and 200 Ampere are used.

7. Coating process according to claim 1,
wherein at least one target is equipped with an additional insulator in the middle, and the arc steering is manipulated in a way for the ceramic target not to crack during arc discharge.

8. Coating process according to claim 1,
wherein Al_{X}Ti_{1-X}N is used as target material, wherein X is ≥75.

9. Coating process according to claim 1,
wherein at least one ceramic target is 99% dense and crack free even during the processing.

10. Coating process according to claim 1,
wherein Al_{X}Ti_{1-X}N is used as target material, wherein the AlN-content is >70 Vol-%, of the target material.

11. Coating process according to claim 1,
wherein nitrogen is introduced as reactive gas.

12. Coating process according to claim 1,
wherein a negative bias voltage (U_{b}) is applied to the substrate to be coated.

13. Coating process according to claim 1,
wherein the deposition temperature during the coating process is lower than 360° C.

14. Coating process according to claim 1,
wherein a plurality of aluminum-rich Al_{X}Ti_{1-X}N-based thin films are deposited one above the other to produce a multilayer film, wherein the content of the Al_{X}Ti_{1-X}N showing a non-columnar microstructure in spite of cubic structure variates with respect to adjacent layers.

15. Aluminium-rich Al_{X}Ti_{1-X}N-based thin film having an aluminium content of >70 at-% based on the total amount of aluminium and titanium in the thin film, a cubic crystal structure and at least partially non-columnar microstructure with a non-columnar content of >1 vol-% based on the total microstructure, producible by a process according to claim 1.

16. Aluminium-rich Al_{X}Ti_{1-X}N-based thin film according to claim 15,
wherein the aluminum-rich Al_{X}Ti_{1-X}N-based thin film having a mixed columnar and non-columnar microstructure with a content of >1 vol-% of the non-columnar microstructure.

17. Aluminium-rich Al_{X}Ti_{1-X}N-based thin film according to claim 15,
wherein the thin film comprises Al, Ti and N as main components and has a chemical elements composition in atomic percentage regarding these elements according to formula (AlₐTi_{b})ₓN_{y}, wherein a and b are respectively the concentration of aluminium and titanium in atomic ratio considering only Al and Ti for the calculation of the element composition in the layer, whereby a+b=1 and 0≠a≥0.7 and 0≠b≥0.2, or 0≠a≥0.8 and 0≠b≤0.2, and wherein x is the sum of the concentration of Al and the concentration of Ti, and y is the concentration of nitrogen in atomic ratio considering only Al, Ti and N for the calculation of the element composition in the layer, whereby x+y=1 and 0.45≤x≤0.55

18. Aluminium-rich AlₓTi₁₋ₓN-based thin film according to claim 15, wherein the thin film shows a hardness (H) of ≥30 GPa measured using instrumented indentation in conformance with ISO 14577-1.

19. Aluminium-rich AlₓTi₁₋ₓN-based thin film according to claim 15, wherein the thin film shows a reduced Young's modulus (Er) in a range between 350 GPa and 480 GPa measured using instrumented indentation in conformance with ISO 14577-1.

20. Aluminium-rich AlₓTi₁₋ₓN-based thin film according to claim 15, wherein the thin film shows a compressive stress of more than 2.5 GPa measured using instrumented indentation in conformance with ISO 14577-1.

21. Aluminium-rich AlₓTi₁₋ₓN-based thin film according to claim 15, wherein the thin film shows a high adhesion of HF 1 even at 5 μm coating thickness, wherein this high adhesion in particular resulting from the deposition of the thin film by the combination of using ceramic targets and arc discharge.

22. Aluminium-rich AlₓTi₁₋ₓN-based thin film according to claim 15, wherein the aluminum-rich Al_{X}Ti_{1-X}N-based thin film is formed as a multilayer film, comprising a plurality of aluminum-rich Al_{X}Ti_{1-X}N-based thin films deposited one above the other.

23. Aluminium-rich AlₓTi₁₋ₓN-based thin film according to claim 15, wherein the thin film has an aluminium content of X≥75.

24. Aluminium-rich AlₓTi₁₋ₓN-based thin film according to claim 15, wherein the layer thickness is >500 nm.

25. Use of an aluminium-rich AlₓTi₁₋ₓN-based thin film according to claim 15 for manufacturing a coated tool or a coated component, especially a coated cutting tool or a coated forming tool or a coated turbine component or a coated component to be used in wear resistant applications.
